(19) United States
(12) Patent Application Publication
(10) Pub. No.: US 2008/0169487 A1
(43) Pub. Date: Jul. 17, 2008

(54) LAYOUT STRUCTURE OF SEMICONDUCTOR INTEGRATED CIRCUIT

(76) Inventors: Hiroyuki Shimbo, Osaka (JP); Hidetoshi Nishimura, Osaka (JP)

Correspondence Address: MCDERMOTT WILL & EMERY LLP, 600 13TH STREET, NW, WASHINGTON, DC, 20005-3096, US

(21) Appl. No.: 11/968,894

(22) Filed: Jan. 3, 2008

(30) Foreign Application Priority Data
Jan. 11, 2007 (JP) 2007-003184

(51) Int. Cl. H01L 27/10

(52) U.S. Cl. 257/207; 257/E27.07

(57) ABSTRACT

In a layout structure of a semiconductor integrated circuit, when transistors are arranged in a constant gate wiring pitch, a common source diffusion region is provided between two adjacent transistors, a CA via is provided on the common source diffusion region, and a source wiring connected to the CA via is provided on the common source diffusion region. An inter-drain wiring connecting the drain regions of the two transistors is formed in a wiring layer higher than the source wiring. Therefore, the wiring path of the source wiring is not limited by the wiring path of the inter-drain wiring, and can be provided, covering the common source diffusion region to a further extent. As a result, the number of high-resistance CA vias or the flexibility of arrangement is increased, leading to a reduction in source resistance, resulting in an increase in operating speed of the semiconductor integrated circuit.

### CROSS REFERENCE TO RELATED APPLICATIONS

This Non-provisional application claims priority under 35 U.S.C. §119(a) on Patent Application No. 2007-003184 filed in Japan on Jan. 11, 2007, the entire contents of which are hereby incorporated by reference.

### BACKGROUND OF THE INVENTION

1. Field of the Invention

The present invention relates to a layout structure of a semiconductor integrated circuit employing standard cells which are each a base unit in the layout of the semiconductor integrated circuit. More particularly, the present invention relates to a layout structure of a semiconductor integrated circuit employing standard cells which have a constant gate wiring pitch of transistors.

2. Description of the Related Art

Conventionally, in order to achieve a low-cost and high-performance semiconductor integrated circuit, attempts have been made to reduce the area of each individual semiconductor integrated circuit to the extent possible without reducing the operating speed so that as many semiconductor integrated circuits as possible can be provided on a single silicon wafer.

Of the attempts, a so-called “miniaturization” has been employed in the field of manufacturing process technology. The term “miniaturization” refers to a technique of improving the design precision of manufacturing technology so as to produce a transistor having a considerably small gate wiring pitch (a distance between each gate wiring) or a CA via (also called a contact or a via hole, which is a rod made of a metal which connects a drain diffusion region or a source diffusion region and a metal wiring) which has a small diameter and can be arranged with high density. By the miniaturization, the number of transistors integrated per unit area can be increased, so that the area of a semiconductor integrated circuit can be reduced.

On the other hand, an advance in the miniaturization has led to two significant problems which directly cause a reduction in operating speed. A first problem is that the operating speed of a semiconductor integrated circuit decreases due to variations in gate length. A second problem is that the operating speed of a semiconductor integrated circuit decreases due to an increase in resistance of a CA via for the source of a transistor.

Firstly, the first problem will now be specifically described. In semiconductor manufacturing processes, photolithography is used in a step of forming a circuit on a silicon substrate. Photolithography generally includes resist coating→prebaking→exposure→development→etching→resist removal. The technique is also used to form a polysilicon wiring which will become a gate wiring of a transistor. The first problem arises during the exposure step.

The exposure step is a step of projecting a circuit pattern drawn on a glass plate (mask) onto a silicon wafer so as to transfer the circuit pattern onto the silicon wafer. In this case, if the circuit pattern is excessively fine, the circuit pattern acts on light waves as if it were a diffraction grating, so that scattered light occurs. In this case, the contour of the pattern transferred on the silicon wafer is expanded due to the scattering as compared to the circuit pattern on the mask. As a result, a significant error occurs in the shape of the transferred circuit pattern.

The shape error increases with a decrease in width or pitch of a pattern drawn on a mask. The gate length of a transistor is strongly affected by the shape error. A change in gate length due to exposure in a semiconductor integrated circuit in which both a plurality of transistors having a narrow gate wiring pitch and a plurality of transistors having a broad gate wiring pitch coexist, will be discussed. In this case, it is assumed that the circuit pattern is drawn on the mask so that the gate length of the transistor having the narrow gate wiring pitch is equal to the gate length of the transistor having the broad gate wiring pitch. If this mask is used to perform exposure, a gate wiring having a certain amount of shape error is formed on a silicon substrate due to the influence of scattered light.

The gate length of a transistor having a narrow gate wiring pitch has a large shape error on the silicon substrate since it is largely affected by scattered light. On the other hand, the gate length of a transistor having a broad gate wiring pitch has a small shape error on the silicon substrate since it is less affected by scattered light. Therefore, although transistor patterns have the same gate length on a mask, transistors formed on the silicon substrate have different gate lengths. Therefore, the transistor gate length has a certain amount of variation.

As described above, if a semiconductor integrated circuit comprising transistors having varying gate wiring pitches is formed on a silicon substrate, then when the transistors are transferred from a mask to a silicon wafer, the gate lengths of the transistors are not uniform, i.e., the gate lengths have a certain amount of variation.

The current drive ability of a transistor is inversely proportional to the gate length. Therefore, a variation in the gate length directly leads to a variation in the current drive ability of the transistor. The operating speed of a semiconductor integrated circuit depends on how quickly a desired capacitance in a circuit can be charged with a predetermined amount of charges. Therefore, the operating speed of a semiconductor integrated circuit is proportional to the current drive ability of a transistor. Therefore, a variation in the current drive ability directly leads to a variation in the operating speed. Since the operating speed of a semiconductor integrated circuit varies from a value estimated during a design stage, it is difficult to obtain a semiconductor integrated circuit having a desired operating speed.

As described above, if an attempt is made to produce a semiconductor integrated circuit having transistors with varying gate wiring pitches using an advanced miniaturization process, the operating speed of the semiconductor integrated circuit is easily deteriorated. The first problem has been described.

In order to solve the first problem, a semiconductor integrated circuit may comprise transistors having a constant gate wiring pitch. For example, Japanese Unexamined Patent Application Publication No. H09-289251 (hereinafter referred to as Patent Document) discloses a layout structure of a semiconductor integrated circuit which employs standard cells in which transistors are arranged in a constant gate wiring pitch.

Patent Document will be described as a conventional example elsewhere below.

Next, the second problem will now be specifically described.

In order to advance the miniaturization, the wiring width of each metal wiring needs to be reduced so as to increase the number of metal wirings per unit area. A metal wiring having a smaller wiring width has a larger resistance value. A metal wiring having a larger resistance value leads to a decrease in propagation speed of a signal propagating through the metal wiring, or a break in the metal wiring due to heat. To avoid this, copper is generally used in an advanced miniaturization process. This is because copper has a resistivity which is ⅔ of that of aluminum, which is conventionally used.

However, when copper contacts a silicon substrate, copper is diffused into the silicon substrate, resulting in a deterioration in electrical characteristics or crystallinity of the silicon substrate. To avoid this, a CA via which connects the diffusion region of a transistor and a metal wiring layer needs to be made of a metal having a high resistance value (tungsten, etc.) other than copper, which has a low resistance. Therefore, such a CA via has a higher resistance than those of a metal wiring layer made of copper and other vias which connect metal wiring layers. For example, tungsten has a resistivity 3.2 times as high as that of copper.

Copper is also diffused in an oxide film. Therefore, if an oxide film which separates a metal wiring layer made of copper from a diffusion region of a transistor is excessively thin, diffused copper is likely to pass through the oxide film and reach the silicon substrate. To avoid this, the oxide film layer formed between the diffusion region of a transistor and the metal wiring layer needs to be sufficiently thick in an advanced miniaturization process.

As a result, a distance between the transistor diffusion region and the metal wiring layer is large, so that the length of a CA via which connects the transistor diffusion region and the metal wiring layer is also large. As a result, the resistance value further increases. Due to the above-described factors, the resistance value of a CA via tends to be large in a semiconductor integrated circuit formed by an advanced miniaturization process.

CA vias are used in a path which connects a diffusion region corresponding to the source of a transistor and a metal wiring corresponding to a power source wiring. Therefore, if a CA via has a high resistance value, a larger voltage drop occurs due to a current which flows through a path from the metal wiring layer to the diffusion region. Therefore, a voltage lower than the voltage of the power source wiring is applied to the source terminal of the transistor. Since the current drive ability of a transistor is proportional to the voltage of the source terminal of the transistor, an increase in resistance value of the CA via directly leads to a decrease in operating speed of the semiconductor integrated circuit.

As described above, when a manufacturing process with advanced miniaturization is used, CA vias have a high resistance, so that the operating speed of a semiconductor integrated circuit tends to decrease. The second problem has been described.

Patent Document does not disclose a means for solving the second problem. Therefore, the layout structure of the semiconductor integrated circuit disclosed in Patent Document has a problem with a decrease in the operating speed. This will be described in detail elsewhere below.

Next, for the first problem, four conventional examples will be described.

Hereinafter, a first conventional example will be described. FIG. 8 is a diagram showing a standard cell (FIG. 1 of Patent Document).

In FIG. 8, the standard cell 1 comprises a P-type diffusion region 2 and an N-type diffusion region 3. Gate wirings 4, 5 and 6 are extended in a direction parallel to the left and right sides of the standard cell 1, and penetrate through the P-type diffusion region 2 and the N-type diffusion region 3. As a result, the gate wirings 4, 5 and 6 function as the gate electrodes of P-channel transistors P1, P2 and P3 in a region overlapping the P-type diffusion region 2, and as the gate electrodes of N-channel transistors N1, N2 and N3 in a region overlapping the N-type diffusion region 3. The gate wirings 6, 5 and 4 have the same wiring pitch.

Power source wirings 11 and 19 are wirings for supplying power source voltages VDD and VSS, respectively, to the source terminal of a transistor in the standard cell 1. The power source wirings 11 and 19 are formed in a metal wiring layer and are extended in parallel along with the upper and lower sides of the standard cell 1.

A CA via 12 is connected to a power source wiring 16 made of the same metal wiring layer as that of the power source wiring 11 and is extruded from the power source wiring 11. The CA via 12 is also provided in a source diffusion region 300 which is a portion of the P-type diffusion region 2 which is located between the P-channel transistors P1 and P2. The CA via 12 is also connected to the source diffusion region 300.

CA vias 13 and 14 are provided adjacent to and to the right of the P-channel transistor P1 and adjacent to and to the left of the P-channel transistor P2, respectively, and are both connected to the P-type diffusion region 2. Further, the CA vias 13 and 14 are connected to each other via an inter-drain wiring 15 formed in a metal wiring layer. The inter-drain wiring 15, and the power source wirings 11 and 16 are all formed in the same metal wiring layer.

FIG. 9 is a circuit diagram of the standard cell of FIG. 8 (FIG. 7(b) of Patent Document). P-channel transistors P1 and P2 have source terminals 22 and 23, respectively, and drain terminals 24 and 25, respectively. The drain terminals 24 and 25 are connected to each other via a wiring 26. The transistors P1 and P2 correspond to the transistors P1 and P2 of FIG. 8, respectively. The CA via 12 of FIG. 8 is connected to both the source terminals 22 and 23. The CA vias 13 and 14 of FIG. 8 are connected to the drain terminals 24 and 25, respectively. The wiring 26 corresponds to the signal wiring 15 of FIG. 8. The first conventional example has been described.

Next, a second conventional example will be described. FIG. 10 shows a standard cell described in claim 1 of Patent Document, which is a standard cell which comprises an inverter logic and in which a plurality of CAs are provided in a source diffusion region so as to prevent a voltage drop at a source terminal.

The standard cell 70 comprises a P-type diffusion region 71 and an N-type diffusion region 72. Gate wirings 81 to 84 which are provided on the P-type diffusion region 71 are arranged in a constant wiring pitch. Portions overlapping the P-type diffusion region 71 of the gate wirings 81 to 84 function as the gate electrodes of P-channel transistors P81 to P84, respectively. The gate wirings 81 to 84 are connected to each other via a polysilicon wiring 86.

Gate wirings 91 to 94 formed on the N-type diffusion region 72 are arranged in a constant wiring pitch. Portions overlapping the N-type diffusion region 72 of the gate wirings 91 to 94 function as the gate electrodes of N-channel transistors N91 to N94, respectively. The gate wirings 91 to 94 are connected to each other via the polysilicon wiring 86. A source diffusion region 101 is a portion of the P-type diffusion region 71 which is located to the left of the gate wiring 81, and corresponds to the source terminal of the P-channel transistor P81.

A source diffusion region 102 is a portion of the P-type diffusion region 71 which is located between the gate wirings 82 and 83, corresponds to the source terminal of a P-channel transistor P82, and corresponds to the source terminal of a P-channel transistor P83. A source diffusion region 103 is a portion of the P-type diffusion region 71 which is located to the right of the gate wiring 84, and corresponds to the source terminal of the P-channel transistor 84. A drain diffusion region 104 is a portion of the P-type diffusion region 71 which is located between the gate wirings 81 and 82, corresponds to the drain terminal of the P-channel transistor P81, and corresponds to the drain terminal of the P-channel transistor P82. A drain diffusion region 105 is a portion of the P-type diffusion region 71 which is located between the gate wirings 83 and 84, corresponds to the drain terminal of the P-channel transistor P83, and corresponds to the drain terminal of the P-channel transistor P84.

Power source wirings 106 and 107 are wirings for supplying power source voltages VDD and VSS, respectively, to the source terminals of transistors in the standard cell 70. The power source wirings 106 and 107 are made of a metal wiring and are arranged in parallel along with the upper and lower sides of the standard cell 70. Power source wirings 110 to 112 are made of a metal wiring, and are arranged in a direction perpendicular to the power source wiring 106.

A drain wiring 140 is formed in a metal wiring layer. CA vias 120 to 123 all connect the power source wiring 110 and the source diffusion region 101, and are provided in the source diffusion region 101. CA vias 124 to 127 all connect a power source wiring 111 and the source diffusion region 102, and are provided in the source diffusion region 102. CA vias 128 to 131 all connect the power source wiring 112 and the source diffusion region 103, and are provided in the source diffusion region 103. CA vias 141 to 144 all connect the drain wiring 140 and the drain diffusion region 104, and are provided in the drain diffusion region 104. CA vias 145 to 148 all connect the drain wiring 140 and the drain diffusion region 105, and are provided in the drain diffusion region 105. The second conventional example has been described.

Next, a third conventional example will be described. FIG. 11 shows a standard cell described in claim 1 of Patent Document, which includes an OR logic. FIG. 12 is a circuit diagram of the standard cell of FIG. 11.

Firstly, the circuit diagram of the OR of FIG. 12 will be described. The OR circuit 2000 has a structure in which the output of a NOR circuit 2010 and the input of an inverter circuit 2020 are connected in series. The output of the inverter circuit 2020 is connected to the output terminal OUT of the OR circuit 2000, so that the output terminal OUT is driven by the inverter circuit 2020.

Next, FIG. 11 will be described. A standard cell 160 includes a NOR circuit 161 and an inverter circuit 162. The NOR circuit 161 corresponds to the NOR circuit 2010 of FIG. 12. The inverter circuit 162 corresponds to the inverter circuit 2020 of FIG. 12. Gate wirings 163 and 164 of P-channel transistors are both arranged in predetermined intervals S. Gate wirings 168 and 169 of N-channel transistors are also arranged in the predetermined intervals S. The third conventional example has been described.

However, the above-described three conventional examples have problems as described below.

In the first conventional example, the inter-drain wiring which is provided between the drain terminals is formed in the same wiring layer as that of the power source wiring, so that a CA via to be connected to the source terminal cannot be placed in a portion of the source diffusion region through which the inter-drain wiring is passed. Therefore, the flexibility of arrangement of a CA via in the source diffusion region decreases, so that the flexibility of adjustment of the source resistance by changing the number of CA vias also decreases, resulting in a decrease in the flexibility of design of a transistor having a high operating speed.

The inter-drain wiring 15 is provided on and horizontally across the source diffusion region 300 of FIG. 8. The power source wiring 16 is formed in the same metal wiring layer as that of the inter-drain wiring 15 and is arranged on and vertically across the source diffusion region 300, and has only a length which causes the power source wiring 16 not to contact the inter-drain wiring 15. The CA via 12 can be provided only in a region which causes the CA via 12 to contact the power source wiring 16, and cannot be provided in a region which causes the CA via 12 to contact the inter-drain wiring 15. Therefore, a CA via cannot be added to a portion on the source diffusion region 300 across which the inter-drain wiring 15 is horizontally arranged. As a result, the flexibility of arrangement of CA vias connected to the source terminal of the P-channel transistors P1 and P2 is reduced by a quantity corresponding to the portion across which the inter-drain wiring 1 is horizontally arranged. Therefore, the number of CA vias arranged is decreased, so that the source resistance increases, resulting in a decrease in the speed of the transistor.

Next, in the case of the second conventional example, as the gate wiring pitch is increased, a diffusion region which is not used as a source diffusion region is similarly broadened. As a result, the drain diffusion region to which the drain terminal of the transistor is connected is also broadened, so that the junction capacitance of the drain diffusion region increases, leading to a decrease in the speed of the semiconductor integrated circuit. Thus, the effect of change of the gate wiring pitch for the purpose of increasing the speed is suppressed. As a result, the flexibility of design of a semiconductor integrated circuit having a higher operating speed decreases (second problem).

The term “junction capacitance” refers to a parasitic capacitance between a diffusion region and a silicon substrate. The smaller the diffusion region, the smaller the junction capacitance. In general, the potential of the drain terminal of a transistor is not constant and is changed between VDD and VSS, depending on a signal propagating through a circuit, as is different from the source terminal. The higher the rate of this change, the higher the operating speed of the semiconductor integrated circuit. In order to increase the change rate of a potential, the capacitance of a terminal at which the potential is generated needs to be reduced. Therefore, the junction capacitance of a diffusion region corresponding to the drain terminal is desirably reduced to the extent possible.

As described above regarding the second problem, the voltage of the source terminal needs to be increased in order to increase the operating speed of a transistor. To achieve this, the number of CA vias which connect the source terminal and the power source wiring may be increased. Therefore, the gate wiring pitch of the transistor needs to be increased. The gate wirings 81 to 84 of FIG. 10 are arranged in a constant gate wiring pitch. The gate wiring pitch has a value such that a total of four CA vias (2 (length)×2 (width)) can be provided in each of the source diffusion regions 101 to 103.

However, since the gate wiring pitch is constant, the areas of the drain diffusion regions 104 and 105 are also large as is similar to the source diffusion regions 101 to 103. Therefore, a diffusion capacitance proportional to the magnitude of the gate wiring pitch occurs in the drain diffusion regions 104 and 105.

Thus, if the gate wiring pitch is constant, the drain diffusion capacitance increases with an increase in the gate wiring pitch. An increase in the drain diffusion capacitance leads to a delay in the potential change of the drain terminal, resulting in a delay in the speed of the semiconductor integrated circuit. Therefore, due to the change of the gate wiring pitch and the addition of a CA via, the speed improving effect is suppressed. Therefore, the flexibility of design of a semiconductor integrated circuit having a higher operating speed by changing the gate wiring pitch decreases.

In the third conventional example, the gate wiring pitch is constant. Therefore, in a multi-stage cell having a circuit structure whose output terminal is driven by an inverter (e.g., an OR circuit), the same gate wiring pitch needs to be applied to an inverter and other circuits. Therefore, a gate wiring pitch suitable for a high-speed operation of the inverter and a gate wiring pitch suitable for a high-speed operation of other circuits cannot coexist in a standard cell. Therefore, the flexibility of design of a semiconductor integrated circuit having a higher operating speed decreases (third problem).

In an inverter 160 of FIG. 11, the NOR circuit 161 and the inverter 162 are arranged adjacent to each other. As a result, gate wirings are also arranged adjacent to each other. Therefore, in order to avoid variations in the transistor gate length, the inverter 160 and the NOR circuit 161 are caused to have the same gate wiring pitch. As a result, a gate wiring pitch suitable for a high-speed operation of the inverter and a gate wiring pitch suitable for a high-speed operation of other circuits cannot coexist in a standard cell. Therefore, the flexibility of design of a semiconductor integrated circuit having a higher operating speed decreases.

### SUMMARY OF THE INVENTION

An object of the present invention is to provide an inter-drain wiring in a wiring layer different from that in which a power source wiring is provided, in order to solve the first problem.

Another object of the present invention is to arrange gate wirings of a plurality of transistors in a manner such that a wiring pitch between each gate wiring is not limited to a single pitch and includes two wiring pitches which are alternately repeated, in order to solve the second problem.

Still another object of the present invention is to provide a double-height cell having a height two times as large as a predetermined height of a standard cell, and arrange a plurality of transistors in an upper half of the double-height cell in a gate wiring pitch suitable for, for example, an increase in the speed of an inverter, while arranging a plurality of transistors in a lower half of the double-height cell in a gate wiring pitch having a high level of flexibility of design of general-purpose circuits, in order to solve the third problem.

To solve the first problem, the present invention provides a layout structure of a semiconductor integrated circuit employing a standard cell. The standard cell includes a silicon substrate, a plurality of transistors provided on the silicon substrate and each having a drain diffusion region, a source diffusion region, and a gate wiring, a first wiring layer made of a metal and provided on the silicon substrate, covering the silicon substrate, a second wiring layer made of a metal and provided above the first wiring layer, covering the first wiring layer, and a CA via for connecting the drain diffusion region or the source diffusion region and the first wiring layer. The standard cell further includes a power source wiring provided in the first wiring layer, and a jumper wiring. The plurality of transistors are arranged in the standard cell in a manner such that a wiring pitch between each gate wiring thereof is constant. The plurality of transistors include first and second transistors. The first transistor and the second transistor are arranged adjacent to each other, sharing a common source diffusion region. A plurality of first CA vias are provided in the common source diffusion region. The plurality of first CA vias are each connected to the power source wiring. The jumper wiring is provided in the second wiring layer and connects the drain diffusion region of the first transistor and the drain diffusion region of the second transistor.

In an example of the semiconductor integrated circuit layout structure of the present invention, the standard cell is an inverter.

In an example of the semiconductor integrated circuit layout structure of the present invention, the plurality of transistors included in the standard cell are a plurality of N-channel transistors.

To solve the second problem, the present invention provides a layout structure of a semiconductor integrated circuit having one or more first standard cell rows each including a plurality of standard cells, each standard cell including a power source wiring, a plurality of transistors, and a plurality of CA vias for connecting drain diffusion regions or source diffusion regions of the plurality of transistors and a metal wiring layer. The plurality of transistors are arranged in a direction parallel to upper and lower sides of the standard cell, gate wirings of the plurality of transistors are arranged in a direction perpendicular to the upper and lower sides of the standard cell, and a wiring pitch between each of the plurality of gate wirings includes a first wiring pitch and a second wiring pitch, the first wiring pitch and the second wiring pitch being alternately repeated. The first wiring pitch is narrower than the second wiring pitch. A first source diffusion region which is at least one of the source diffusion regions provided between a pair of gate wirings having the second wiring pitch is connected via a plurality of CA vias to the power source wiring. At least one pair of two of the plurality of CA vias are arranged in a direction parallel to the upper and lower sides of the standard cell.

In an example of the semiconductor integrated circuit layout structure of the present invention, the standard cell is an inverter or a buffer.

In an example of the semiconductor integrated circuit layout structure of the present invention, a second standard cell row is further included which has a plurality of standard cells including a plurality of transistors arranged in a single gate wiring pitch.

In an example of the semiconductor integrated circuit layout structure of the present invention, first and second circuit blocks and at least one repeater block are further included. The repeater block includes at least one of the first standard cell rows including a first standard cell having an inverter or buffer function. A signal output from the first circuit block is input to the first standard cell. A signal output from the first standard cell is input to the second circuit block.

In an example of the semiconductor integrated circuit layout structure of the present invention, the first circuit block includes at least one of the first standard cell rows including the first standard cell having an inverter or buffer function. A signal output from the first circuit block is a signal output from the first standard cell and is transferred to the second circuit block.

To solve the third problem, the present invention provides a layout structure of a semiconductor integrated circuit including a plurality of standard cell rows each including a plurality of standard cells, each standard cell including a plurality of transistors each having a diffusion region and a gate wiring, and a plurality of CA vias for connecting drain diffusion regions or source diffusion regions of the plurality of transistors and a metal wiring layer, and the standard cells being arranged in a direction parallel to upper and lower sides of the standard cell. The layout structure includes a first standard cell row including some of the plurality of transistors arranged at predetermined intervals in a manner such that a wiring pitch between each gate wiring of the transistor is a first wiring pitch S, a second standard cell row including some of the plurality of transistors arranged in a manner such that a wiring pitch between each gate wiring of the transistor includes a second wiring pitch S1 and a third wiring pitch S0 larger than the second wiring pitch S1, the second wiring pitch S1 and the third wiring pitch S0 being alternately repeated, the first standard cell row and the second standard cell row being vertically adjacent to each other, and at least one double-height cell overlapping the first and second standard cell rows.

In an example of the semiconductor integrated circuit layout structure of the present invention, the third wiring pitch S0 is larger than the first wiring pitch S. The maximum number of CA vias which can be arranged without contacting each other in a direction parallel to the upper and lower sides of the standard cell on a diffusion region between two adjacent gate wirings having the third wiring pitch S0, is larger than the maximum number of CA vias which can be arranged without contacting each other in the direction parallel to the upper and lower sides of the standard cell on a diffusion region between two adjacent gate wirings having the third wiring pitch S.

In an example of the semiconductor integrated circuit layout structure of the present invention, the double-height cell includes a plurality of first transistors. The plurality of first transistors are provided in the second standard cell row when the double-height cell is provided in the semiconductor integrated circuit. The plurality of first transistors are arranged in a manner such that a wiring pitch between each of the plurality of gate wirings includes the second wiring pitch S1 and the third wiring pitch S0, the second wiring pitch S1 and the third wiring pitch S0 being alternately repeated. The plurality of first transistors constitute an output circuit for outputting a signal to be propagated to another one of the standard cells in the semiconductor integrated circuit.

In an example of the semiconductor integrated circuit layout structure of the present invention, the output circuit is an inverter.

According to the present invention, in order to solve the first problem, an inter-drain wiring which is formed in a wiring layer different from that of a power source wiring is provided between drain terminals. Therefore, a CA via can be provided even in a portion of the source diffusion region on which the inter-drain wiring is provided. Therefore, as compared to the first conventional example, the flexibility of arrangement of a CA via in the source diffusion region is improved, and therefore, the flexibility of adjustment of source resistance by changing the number of CA vias is also improved, so that the flexibility of design of a transistor having a higher operating speed is improved.

Also, according to the present invention, in order to solve the second problem, a standard cell is provided which includes two kinds of diffusion regions, i.e., a broad diffusion region in which a plurality of CA vias can be arranged in a horizontal direction, and a diffusion region narrower than the broad diffusion region, without leading to variations in gate length. Therefore, by using the broad diffusion region as a source diffusion region and the narrow diffusion region as a drain diffusion region, a plurality of CA vias can be provided in the source diffusion region without an increase in junction capacitance of the drain diffusion region. As a result, the operating speed of a transistor can be caused to be higher than in the second conventional example. Therefore, the effect of change of a gate wiring pitch so as to achieve high speed is improved, thereby improving the flexibility of design of a semiconductor integrated circuit having a higher operating speed.

Also, according to the present invention, in order to solve the third problem, the double-height cell can include two kinds of transistors: transistors having a first gate wiring pitch which is suitable for an increase in the speed of an inverter, but is not suitable for an increase in the speed of general-purpose circuits; and transistors having a second gate wiring pitch which cannot increase the speed of an inverter and provides a high level of design flexibility with respect to general-purpose circuits as compared to the first gate wiring pitch. Therefore, in a multi-stage cell having a circuit structure in which the output terminal is driven by an inverter, by using the two kinds of transistors separately for an inverter and other circuits, the flexibility of design of a semiconductor integrated circuit having a higher operating speed is more improved than in the third conventional example.

### BRIEF DESCRIPTION OF THE DRAWINGS

FIG. 1 is a diagram showing a standard cell according to a first example of the present invention.

FIG. 2 is a diagram showing a standard cell according to a variation of the first example.

FIG. 3 is a diagram showing a layout configuration of the standard cell of FIG. 2.

FIG. 4 is a diagram showing a standard cell according to a second example of the present invention.

FIG. 5 is a diagram showing an exemplary semiconductor integrated circuit employing the standard cell of FIG. 4.

FIG. 6 is a diagram showing a standard cell according to a third example of the present invention.

FIG. 7 is a diagram showing an exemplary semiconductor integrated circuit employing the standard cell of FIG. 6.

FIG. 8 is a diagram showing a conventional standard.

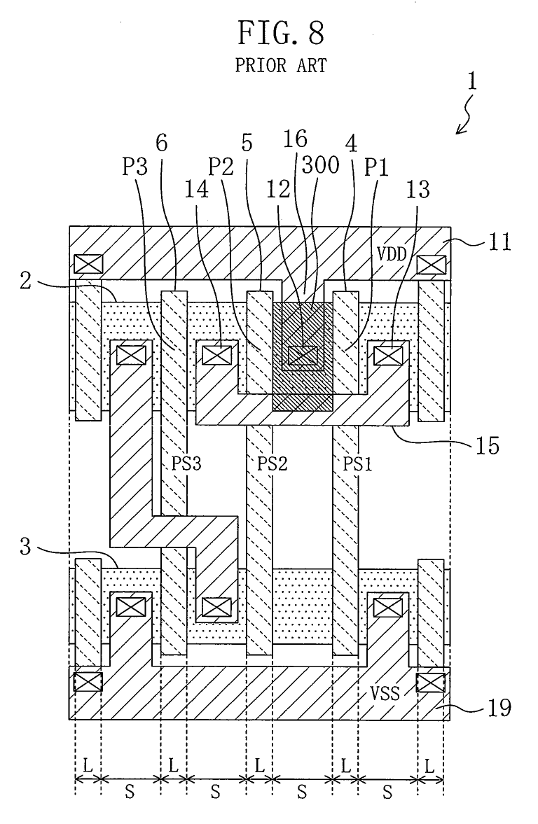

FIG. 9 is a diagram showing a circuit configuration of the standard cell of FIG. 8.

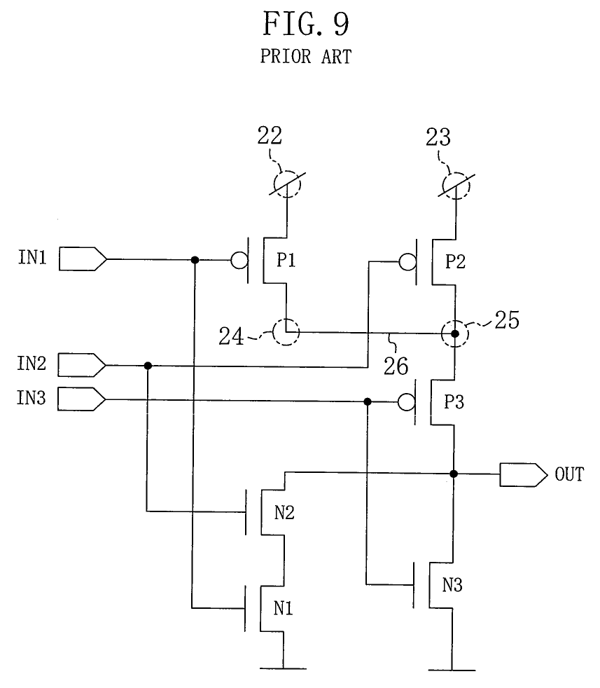

FIG. 10 is a diagram showing a conventional standard cell including an inverter logic.

FIG. 11 is a diagram a conventional standard cell which is a multi-stage cell including an OR logic.

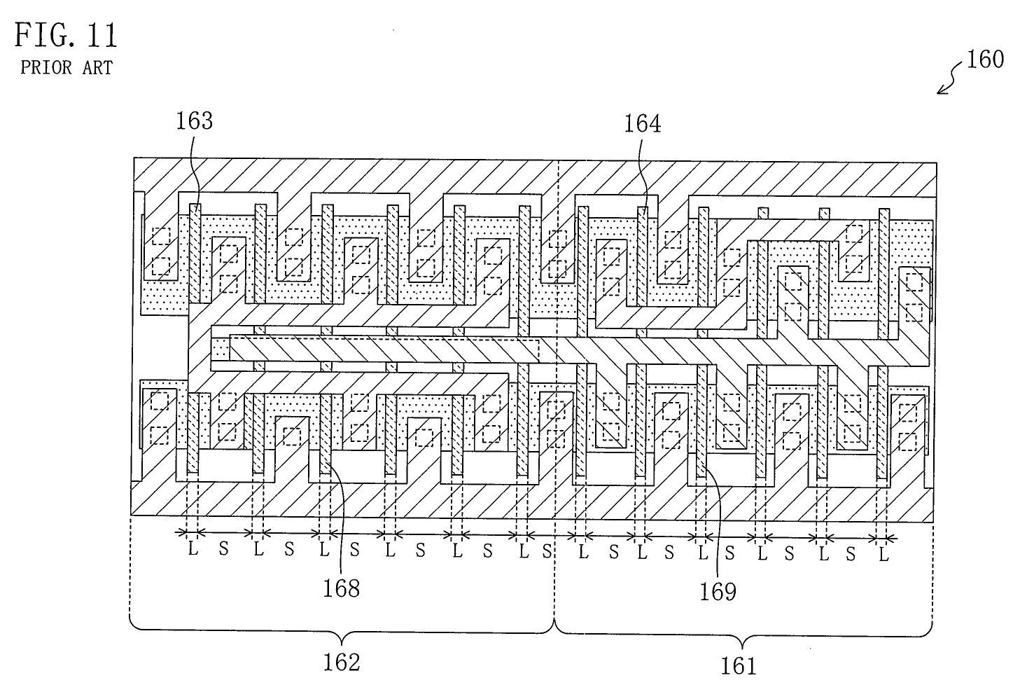

FIG. 12 is a diagram showing a layout configuration of the standard cell of FIG. 11.

### DETAILED DESCRIPTION OF THE PREFERRED EMBODIMENTS

Hereinafter, preferred examples of the present invention will be described with reference to the accompanying drawings.

### First Example

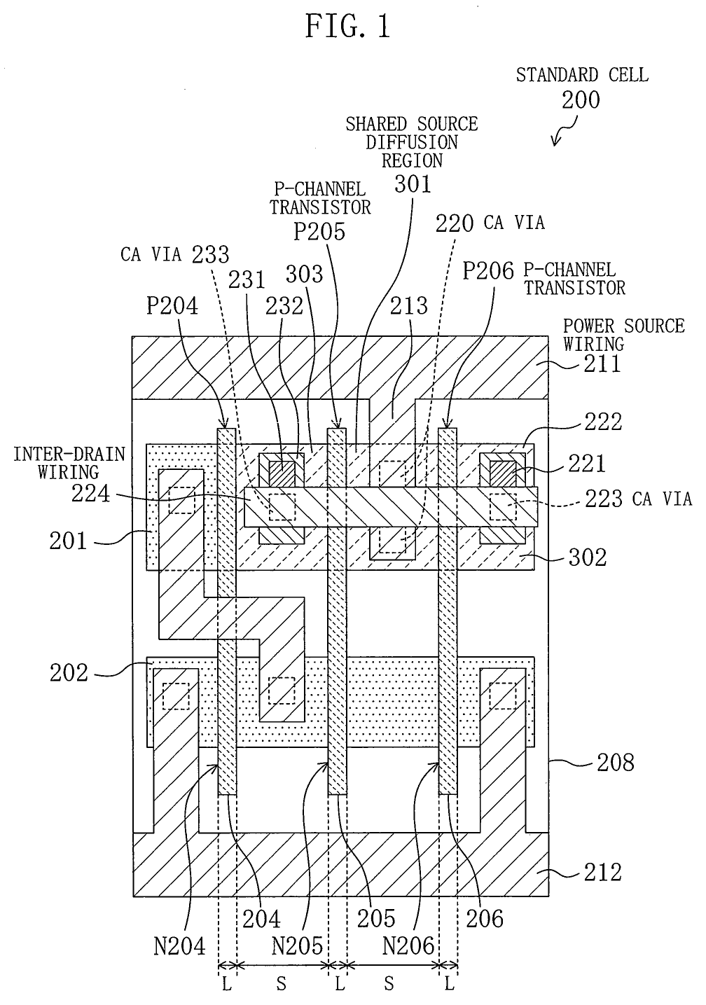

FIG. 1 shows a layout configuration of a standard cell according to this example.

In FIG. 1, the standard cell 200 comprises a P-type diffusion region 201 and an N-type diffusion region 202 on a silicon substrate (not shown). Gate wirings 204 to 206 with a wiring width L are arranged in a direction perpendicular to the upper and lower sides of the standard cell 200 and in a gate wiring pitch S. The gate wirings 204 to 206 function as the gate electrodes of P-channel transistors P204 to P206 in a region overlapping the P-type diffusion region 201, and similarly, function as the gate electrodes of N-channel transistors N204 to N206 in a region overlapping the N-type diffusion region 202.

A source diffusion region 301 is a portion of the P-type diffusion region 201 which is located between the gate wirings 205 and 206 of the two adjacent P-type transistors (first and second transistors) P205 and P206, and is connected to the source terminals of the P-type transistors P205 and P206.

A drain region 302 is a portion of the P-type diffusion region 201 which is located to the right of the gate wiring 206, and is connected to the drain terminal of the P-type transistor P206. A drain region 303 is a portion of the P-type diffusion region 201 which is located between the gate wirings 205 and 204, and is connected to the drain terminal of the P-type transistor P205.

Power source wirings 211 and 212 are formed in a first metal wiring layer, extending in parallel along with the upper and lower sides of the standard cell 200, respectively, and are used to supply power source voltages VDD and VSS, respectively, to the source terminals of the transistors in the standard cell 200. A power source wiring 213 is formed in the first metal wiring layer (first wiring layer), entering from the power source wiring 211 into a source diffusion region 301 in a direction perpendicular to the power source wiring 211.

A CA via 220 includes two CA vias, connects the power source wiring 213 and the source diffusion region 301, and is provided in the source diffusion region 301.

A CA via 221 connects a drain wiring 222 (first metal wiring) and the drain diffusion region 302, and is provided in the drain diffusion region 302. A V1 via 223 connects an inter-drain wiring (jumper wiring) 224 and the drain wiring 222. A CA via 231 connects a drain wiring 232 (first metal wiring) and the drain diffusion region 303, and is provided in the drain diffusion region 303. A V1 via 233 connects the inter-drain wiring 224 and the drain wiring 232.

The inter-drain wiring (jumper line) 224 is formed in a second metal wiring layer (second wiring layer) which is located higher than the first metal wiring layer (first wiring layer), and is arranged in a direction parallel to the upper and lower sides of the standard cell 200. The inter-drain wiring 224 is extended from the inside to the outside of the drain diffusion region 302, is also extended into the drain diffusion region 303, and is extended horizontally across the shared source diffusion region 301. The inter-drain wiring 224 connects the drain diffusion region 303 and the drain diffusion region 302.

Note that, in FIG. 1, a metal wiring or a polysilicon wiring corresponding to the input terminal and the output terminal, the structures of the N-channel transistor, and connections between the terminals and the wirings are not shown for the sake of simplicity.

The above-described example has effects described below. Specifically, the inter-drain wiring 224 connecting the drain diffusion regions 302 and 303 is formed in the second metal wiring layer. On the other hand, the power source wiring 213 is formed in the first metal wiring layer below the second metal wiring layer.

Therefore, the power source wiring 213 is not affected by the wiring path of the inter-drain wiring 224, and can be freely arranged in the source diffusion region 301. Therefore, the CA via 220 provided below the power source wiring 213 can be arranged without constraints from the influence of the wiring path of the inter-drain wiring 224.

As described above, an inter-drain wiring which is formed in a wiring layer different from that of a power source wiring is provided between drain terminals. Therefore, the CA via 220 can be provided in a portion of the source diffusion region 301 on which the inter-drain wiring is provided. Therefore, as compared to the first conventional example, the flexibility of arrangement of the CA via 220 in the source diffusion region 301 is improved, and therefore, the flexibility of adjustment of source resistance by changing the number of CA vias is also improved, so that the flexibility of design of a transistor having a higher operating speed is improved.

Although the number of CA vias 220 is assumed to be two in FIG. 1, the number is not limited to this. Also, the conductivity type of a transistor to which the above-described layout structure is applied is not limited to P-channel, and may be of N-channel.

### Variation of First Example

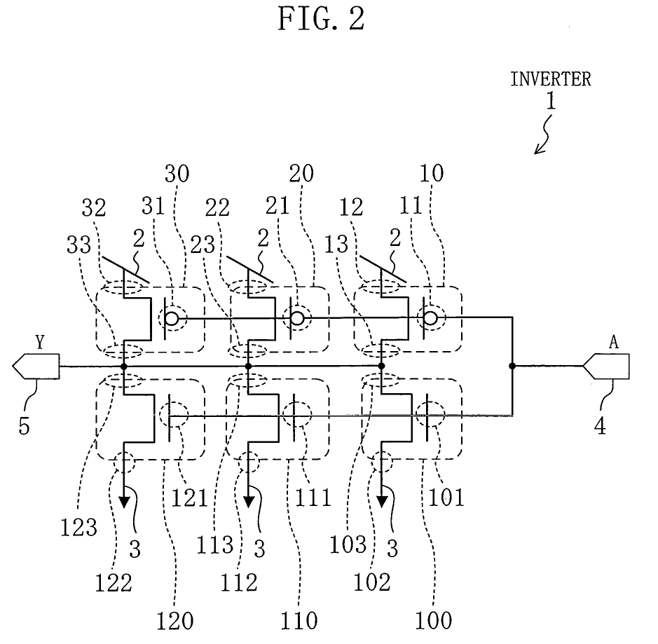

FIG. 2 shows a variation of the first example in which the present invention is applied to an inverter which is a semiconductor integrated circuit.

In FIG. 2, the inverter 1 includes P-channel transistors 10, 20 and 30, and N-channel transistors 100, 110 and 120. The gate terminals 11, 21 and 31 of the P-channel transistors 10, 20 and 30 are all connected to an input terminal 4. The source terminals 12, 22 and 32 of the P-channel transistors 10, 20 and 30 are all connected to a VDD power source 2. The VDD power source 2 has a predetermined potential VDD.

The drain terminals 13, 23 and 33 of the P-channel transistors 10, 20 and 30 are all connected to an output terminal 5. The gate terminals 101, 111 and 121 of the N-channel transistors 100, 110 and 120 are all connected to the input terminal 4. The source terminal 102, 112 and 122 of the N-channel transistor 100, 110 and 120 are all connected to a VSS power source 3. The VSS power source 3 has a ground potential VSS. The drain terminals 103, 113 and 123 of the N-channel transistors 100, 110 and 120 are all connected to the output terminal 5.

Note that the transistors each have a substrate terminal, which is not shown for the sake of simplicity.

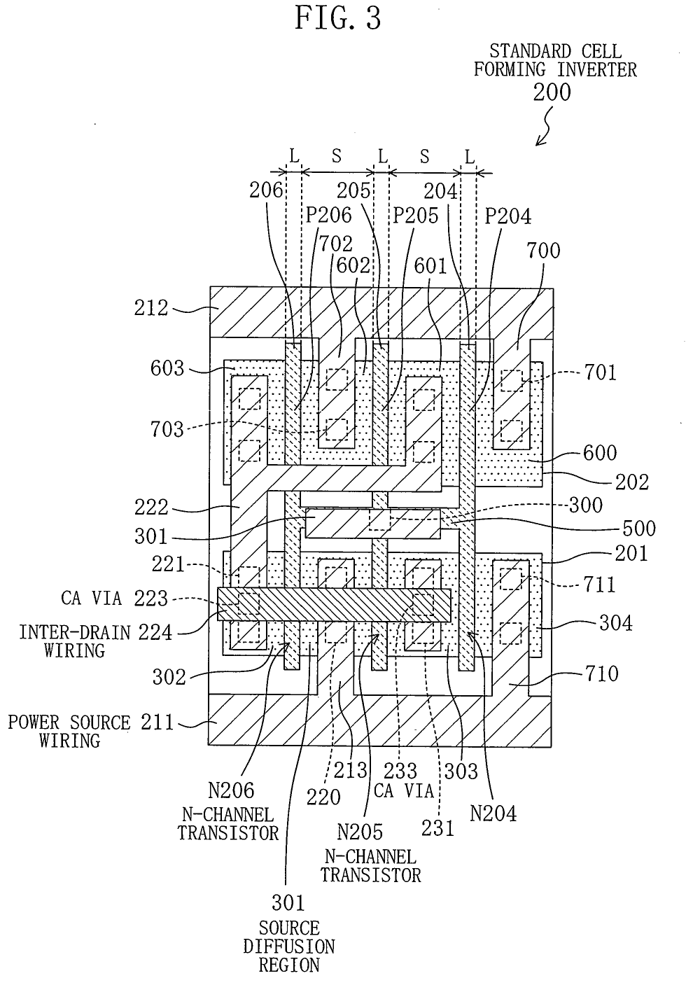

FIG. 3 shows a specific layout configuration of the inverter of FIG. 2. In FIG. 3, a standard cell 200 forming the inverter includes an N-type diffusion region 201 and a P-type diffusion region 202. Gate wirings 204 to 206 with a wiring width L are arranged in a direction perpendicular to the upper and lower sides of the standard cell 200 and in a gate wiring pitch S.

The gate wirings 204 to 206 function as the gate electrodes of N-channel transistors N204 to N206 in a region overlapping the N-type diffusion region 201, respectively, and correspond to the gate terminals 101, 111 and 121 of the circuit of FIG. 2, respectively. Similarly, the gate wirings 204 to 206 function as the gate electrodes of P-channel transistors P204 to P206 in a region overlapping the P-type diffusion region 202, respectively, and correspond to the gate terminals 11, 21 and 31 of the circuit of FIG. 2, respectively. A gate wiring 500 is extended in a direction in parallel to the upper and lower sides of the standard cell 200, and is arranged in a manner such that the gate wiring 500 does not contact the N-type diffusion region 201 or the P-type diffusion region 202 and is electrically connected to the gate wirings 204 to 206.

A CA via 300 is formed on the gate wiring 500, and is electrically connected to the gate wiring 500. A metal wiring 301 is electrically connected via the CA via 300 to the gate wiring 500, and corresponds to the input terminal 4 of the circuit of FIG. 2.

A source diffusion region 600 is a portion of the P-type diffusion region 202 which is located to the right of the gate wiring 204, and corresponds to the source terminal 12 of the circuit of FIG. 2. A drain diffusion region 601 is a portion of the P-type diffusion region 202 which is located between the gate wirings 204 and 205, and corresponds to the drain terminal 13 and the drain terminal 23 of the circuit of FIG. 2. A source diffusion region 602 is a portion of the P-type diffusion region 202 which is located between the gate wirings 205 and 206, and corresponds to the source terminal 22 and the source terminal 32 of the circuit of FIG. 2. A drain diffusion region 603 is a portion of the P-type diffusion region 202 which is located to the left of the gate wiring 206, and corresponds to the drain terminal 33 of the circuit of FIG. 2.

A power source wiring 212 is formed in the first metal wiring layer, and is arranged in parallel with the upper side of the standard cell 200. A power source voltage VDD is applied to the power source wiring 212. The power source wiring 212 corresponds to the VDD power source 2 of the circuit of FIG. 2. A power source wiring 700 is formed in the first metal wiring layer. The power source wiring 700 is electrically connected to the power source wiring 212, is orthogonal to the power source wiring 212, and enters above the source diffusion region 600. The power source wiring 700 is electrically connected via a CA via 701 to the source diffusion region 600. A power source wiring 702 is formed in the first metal wiring layer. The power source wiring 702 is electrically connected to the power source wiring 212, is orthogonal to the power source wiring 212, and enters above the source diffusion region 602. The power source wiring 702 is electrically connected via a CA via 703 to the source diffusion region 602.

A source diffusion region 301 is a portion of the N-type diffusion region 201 which is located between the gate wirings 205 and 206 of the two N-channel transistors N205 and N206 and is shared by the two N-channel transistors N205 and N206. The source diffusion region 301 corresponds to the source terminal 112 and the source terminal 122 of the circuit of FIG. 2. A drain diffusion region 302 is a portion of the N-type diffusion region 201 which is located to the left of the gate wiring 206, and corresponds to the drain terminal 123 of the circuit of FIG. 2. A drain diffusion region 303 is a portion of the N-type diffusion region 201 which is located between the gate wiring 204 and the gate wiring 205, and corresponds to the drain terminal 113 and the drain terminal 103 of the circuit of FIG. 2. A source diffusion region 304 is a portion of the N-type diffusion region 201 which is located to the right of the gate wiring 204, and corresponds to the source terminal 102 of the circuit of FIG. 2.

A power source wiring 211 is formed in the first metal wiring layer, and is arranged in parallel with the lower side of the standard cell 200. The ground voltage VSS is applied to the power source wiring 211. The power source wiring 211 corresponds to the VSS power source 3 of the circuit of FIG. 2. A power source wiring 710 is formed in the first metal wiring layer. The power source wiring 710 is electrically connected to the power source wiring 211, is orthogonal to the power source wiring 211, and enters above the source diffusion region 304. The power source wiring 710 is electrically connected via a CA via 711 to the source diffusion region 304. A power source wiring 213 is formed in the first metal wiring layer. The power source wiring 213 enters from the power source wiring 211 into above the source diffusion region 301 in a direction perpendicular to the power source wiring 211.

A CA via 220 includes two CA vias, connects the power source wiring 213 and the source diffusion region 301, and is provided in the source diffusion region 301.

A CA via 221 connects a drain wiring 222 (first metal wiring) and the drain diffusion region 302, and is provided in the drain diffusion region 302. A V1 via 223 connects an inter-drain wiring (jumper wiring) 224 and the drain wiring 222. A CA via 231 connects a drain wiring 232 (first metal wiring) and a drain diffusion region 303, and is provided in the drain diffusion region 303. A V1 via 233 connects the inter-drain wiring 224 and the drain wiring 232.

The inter-drain wiring (jumper line) 224 is formed in a second metal wiring layer (second wiring layer) which is located higher than the first metal wiring layer (first wiring layer), and is arranged in a direction parallel to the upper and lower sides of the standard cell 200. The inter-drain wiring 224 is extended from the inside to the outside of the drain diffusion region 302, is extended into the drain diffusion region 303, and is extended horizontally across the shared source diffusion region 301. The inter-drain wiring 224 connects the drain diffusion region 303 and the drain diffusion region 302.

The metal wiring 222 is formed in the first metal wiring layer, entering above the drain diffusion region 302, the drain diffusion region 303, the drain diffusion region 601, and the drain diffusion region 603. The metal wiring 222 is electrically connected via CA vias to the drain diffusion region 302, the drain diffusion region 303, the drain diffusion region 601, and the drain diffusion region 603. The metal wiring 222 corresponds to the output terminal 5 of the circuit of FIG. 2.

The above-described configuration of this example provides the following effects. Firstly, by applying the inter-drain wiring 224 only to N-channel transistors, a wiring region of the first metal wiring layer can be broadened in an N-channel transistor region whose wiring region is smaller than that of a P-channel transistor region in the standard cell 200, so that the flexibility of arrangement of CA vias in the source region is further improved. Therefore, the flexibility of design of a standard cell having a higher speed is further improved.

Also, by applying the standard cell 200 to an inverter, the inverter can be used to achieve high-speed signal propagation when a long-distance metal wiring is driven. Therefore, it is possible to increase the speed of communication between large-scale blocks. Therefore, it is particularly possible to increase the speed of a processor which simultaneously processes a large amount of data, such as a processor for a digital television.

### Second Example

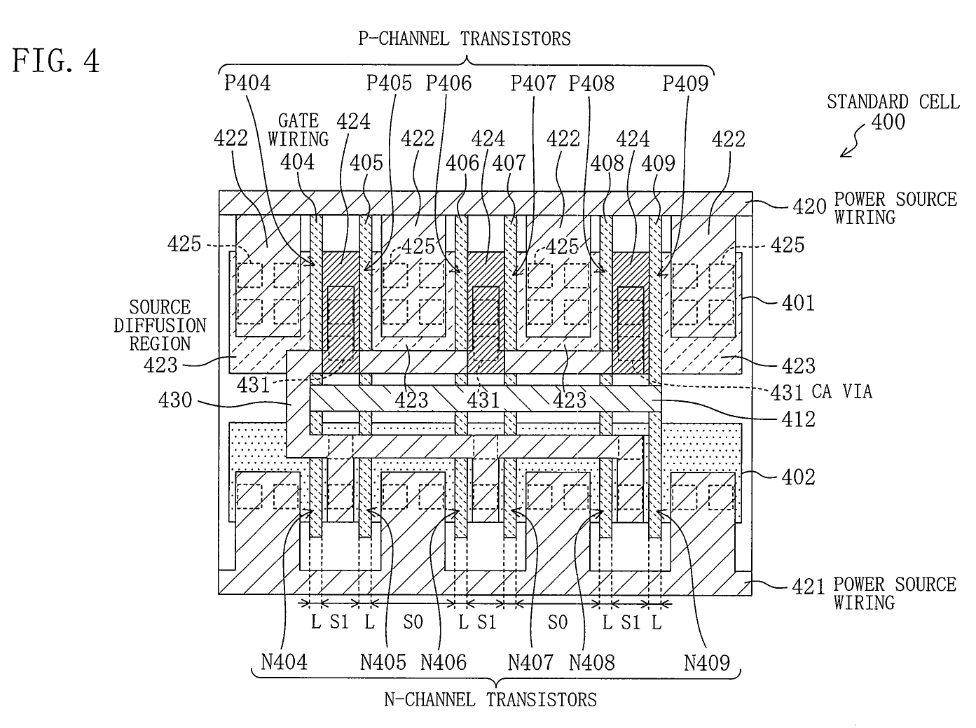

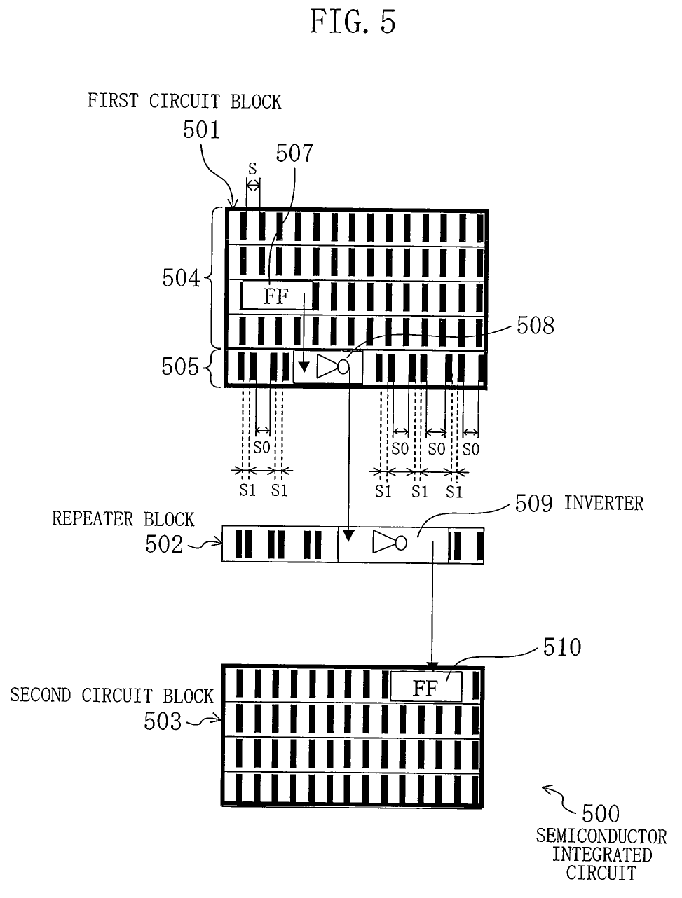

FIG. 4 shows a standard cell according to a second example of the present invention. FIG. 5 shows a layout structure of a semiconductor integrated circuit using the standard cell of FIG. 4. Hereinafter, FIGS. 4 and 5 will be described in detail.

Firstly, FIG. 4 will be described. In FIG. 4, the standard cell 400 comprises a P-type diffusion region 401 and an N-type diffusion region 402. Gate wirings 404 to 409 with a wiring width L are arranged in a direction perpendicular to the upper and lower sides of the standard cell 400. The gate wirings 404 to 409 of P-channel transistors P404 to P409 and N-channel transistors N404 to N409 have a first wiring pitch S0 and a second wiring pitch S1, which are alternately repeated. Specifically, a wiring pitch between the gate wiring 405 and the gate wiring 406 is the first wiring pitch S0, and a wiring pitch between the gate wiring 406 and the gate wiring 407 is the second wiring pitch S1. A wiring pitch between the gate wirings of two adjacent transistors alternately takes the first wiring pitch S0 or the second wiring pitch S1. Here, the first wiring pitch S0 is larger than the second wiring pitch S1 (S0>S1).

The gate wirings 404 to 409 function as the gate electrodes of the P-channel transistors P404 to P409 in a region overlapping the P-type diffusion region 401, and as the gate electrodes of the N-channel transistors N404 to N409 in a region overlapping the N-type diffusion region 402.

Source diffusion regions (first source diffusion regions) 423 are portions of the P-type diffusion region 401 which are located in sections having the first wiring pitch S0. Specifically, the source diffusion regions 423 are a total of four portions of the P-type diffusion region 401: a portion which is located to the left of the gate wiring 404; a portion which is located between the gate wiring 405 and the gate wiring 406; a portion which is located between the gate wiring 407 and the gate wiring 408; and a portion which is located to the right of the gate wiring 409. The source diffusion regions 423 are connected to the source terminals of the respective corresponding P-channel transistors P404 to P409.

Drain diffusion regions 424 are portions of the P-type diffusion region 401 each of which is located between a corresponding pair of gate wirings having the gate wiring pitch S1. Specifically, the drain diffusion regions 424 are a total of three portions of the P-type diffusion region 401: a portion which is located between the gate wiring 404 and the gate wiring 405; a portion which is located between the gate wiring 406 and the gate wiring 407; and a portion which is located between the gate wiring 408 and the gate wiring 409. The drain diffusion regions 424 are connected to the drain terminals of the respective corresponding P-channel transistors P404 to P409.

A polysilicon wiring 412 is arranged in parallel with the upper and lower sides of the standard cell 400, connecting the gate wirings 404 to 409 together, and connecting the gate electrodes of the P-channel transistors P404 to P409 together.

Power source wirings 420 and 421 are formed in a first metal wiring layer. The power source wirings 420 and 421 supply a power source voltage VDD and a ground voltage VSS, respectively, to the source terminals of the transistors in the standard cell 400. The power source wirings 420 and 421 are arranged in parallel along with the upper side and lower side of the standard cell 400, respectively.

A power source wiring 422 is formed in the first metal wiring layer. The power source wiring 422 is connected to the power source wiring 420, is arranged in a direction perpendicular to the power source wiring 420, and enters above the source diffusion region 423.

A total of four CA vias 425 (two (length)×two (width)) are provided in each of the source diffusion regions 423 to connect the source diffusion region 423 and the power source wiring 422 provided above the source diffusion region 423.

A drain wiring 430 is formed in the first metal wiring layer and is passed above and across the drain diffusion region 424. A total of two CA vias 431 (two (length)×one (width) are provided in each of the drain diffusion regions 424 to connect the drain diffusion region 424 and the drain wiring 430.

Note that an output terminal of the standard cell 400 is connected to the drain wiring 430, and an input terminal of the standard cell 400 is connected to the polysilicon wiring 412, though they are not shown in FIG. 4.

Thus, the source terminals of the P-channel transistors P404 to P409 are all connected to the power source wiring 420, the drain terminals of the P-channel transistors P404 to P409 are all connected via the common drain wiring 430 to the output terminal, and the gate terminals of the P-channel transistors P404 to P409 are all connected via the common polysilicon wiring 412 to the input terminal. The thus-configured circuit structure is equivalent to the P-channel transistor of an inverter in terms of a logic circuit.

The source terminals, drain terminals, and gate terminals of the N-channel transistors N404 to N409 are connected in a manner similar to that of the P-channel transistors P404 to P409 and will not be described for the sake of simplicity. As a result, the source terminals of the N-channel transistors N404 to N409 are all connected to the power source wiring 421, the drain terminals of the N-channel transistors N404 to N409 are all connected via the common drain wiring 430 to the output terminal, and the gate terminals of the N-channel transistors N404 to N409 are all connected to the common polysilicon wiring 412. The thus-configured circuit structure is equivalent to the N-channel transistor of an inverter in terms of a logic circuit. Therefore, the standard cell 400 has the logic of an inverter.

The above-described configuration provides effects described below. Firstly, a gate wiring pitch will be described.

Firstly, the gate wiring 405 forming the gate electrode of the N-channel transistor N405 will be described. The gate wiring 405 is adjacent to the gate wiring 404 via the gate wiring pitch S1. The gate wiring 405 is also adjacent to the gate wiring 406 via the gate wiring pitch S0. Therefore, the gate wiring 405 is adjacent to two gate wirings. A gate wiring pitch between the gate wiring 405 and one of the gate wirings is the first wiring pitch S0, and a gate wiring pitch between the gate wiring 405 and the other gate wiring is the second wiring pitch S1.

Next, the gate wiring 406 forming the gate electrode of the N-channel transistor N406 will be described. The gate wiring 406 is adjacent to the gate wiring 407 via the second gate wiring pitch S1. The gate wiring 406 is also adjacent to the gate wiring 405 via the first gate wiring pitch S0. Therefore, the gate wiring 406 is adjacent to two gate wirings. A gate wiring pitch between the gate wiring 406 and one of the gate wirings is the first wiring pitch S0, and a gate wiring pitch between the gate wiring 406 and the other gate wiring is the second wiring pitch S1.

Thus, it is understood that the gate wiring 406 and the gate wiring 405 both have the first gate wiring pitches S0 and S1 with respect to adjacent wirings. As a result, an error in gate wiring width occurring during transfer onto a silicon substrate due to scattered light caused by diffraction is the same between the gate wiring 405 and the gate wiring 406.

Therefore, the gate length of the P-channel transistor P405 and the gate length of the P-channel transistor P406 have the same error, so that the gate length does not vary between the P-channel transistors P405 and P406.

Gate wirings are provided in the standard cell 400 in a manner such that a combination of gate wiring pitches as possessed by the two gate wirings 405 and 406 are repeatedly arranged in a direction parallel to the upper and lower sides of the standard cell 400. Therefore, the gate lengths of the P-channel transistors included in the standard cell 400 do not vary due to the influence of scattered light caused by diffraction.

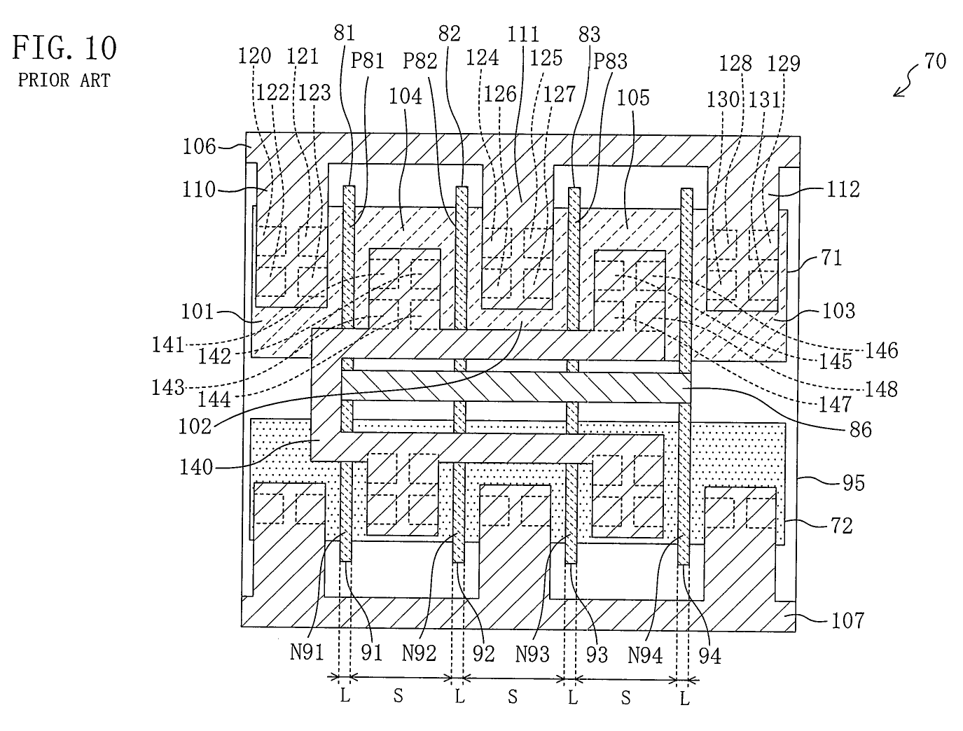

Next, an increase in speed of an inverter by the above-described configuration will be described. In the second conventional example, as shown in FIG. 10, since the gate wiring pitch is constant, the drain diffusion regions 104 and 105 having the same size as that of the source diffusion regions 101 to 103 are provided.

On the other hand, in FIG. 4 of this example, two kinds of gate wiring pitches (the first and second wiring pitches S0 and S1) are provided in the standard cell 400. A source diffusion region 425 of a P-channel transistor included in an inverter is provided in a region having the first wiring pitch S0, while a drain diffusion region 424 of the P-channel transistor included in the inverter is provided in a region having the second wiring pitch S1. In this case, since the second gate wiring pitch S1 is smaller than the first wiring pitch S0, the drain diffusion region 424 can be caused to be smaller than the source diffusion region 425. Therefore, the diffusion capacitance of the drain of an inverter having the structure of the present invention can be caused to be smaller than in the second conventional example. Therefore, it is possible to design an inverter having a higher speed.

Although an inverter has been described in FIG. 5, a similar effect is obtained even in the case of a buffer including two inverter connected in series.

As described above, it is possible to provide a standard cell including two kinds of diffusion regions, i.e., a broad diffusion region in which a plurality of CA vias can be arranged in a horizontal direction, and a diffusion region narrower than the broad diffusion region, without leading to variations in gate length. Therefore, by using the broad diffusion region as a source diffusion region and the narrow diffusion region as a drain diffusion region, a plurality of CA vias can be provided in the source diffusion region without an increase in junction capacitance of the drain diffusion region. As a result, the operating speed of a transistor can be caused to be higher than in the second conventional example. Therefore, the effect of change of a gate wiring pitch so as to achieve high speed is improved, thereby improving the flexibility of design of a semiconductor integrated circuit having a higher operating speed. FIG. 4 has been described.

Next, FIG. 5 will be described. A semiconductor integrated circuit 500 comprises first and second circuit blocks 501 and 503, and a repeater block 502.

The first circuit block 501 includes an output circuit section 505 and a logic circuit section 504. The output circuit section 505 has a first standard cell row including transistors which are arranged in a manner such that a first gate wiring pitch S0 and a second gate wiring pitch S1 are alternately repeated. The logic circuit section 504 has a second standard cell row including transistors which are arranged at predetermined intervals in a manner such that a wiring pitch between each gate wiring is a predetermined wiring pitch S. A flip-flop 507 is provided in the logic circuit section 504, and is arranged to receive a calculation result of the logic circuit section 504 and output a signal to an inverter 508. The inverter 508 has the same structure as that of the inverter of FIG. 4. The inverter 508 is provided in the output circuit section 505, and is arranged to receive a signal output from the flip-flop 507 and output a signal to an inverter 509 (described below) in the repeater block 502.

The inverter 509 (a first standard cell which is a driver cell having an inverter function) has the same structure as that of the inverter of FIG. 4. The inverter 509 is provided in the repeater block 502, and is arranged to receive a signal output from the inverter 508 in the first circuit block 501 and output a signal to a flip-flop 510 in the second circuit block 503 as an output circuit of the repeater block 502.

The flip-flop 510 is provided in the circuit block 503, and is arranged to receive a signal output from the inverter 509.

The above-described configuration provides effects described below. Firstly, a relationship between light scattering caused by diffraction and a gate wiring pitch in a standard cell row will be described.

As described above, light scattering caused by diffraction occurring at a gate wiring during exposure varies depending on a wiring pitch between laterally adjacent gate wirings. Strictly speaking, however, the cause of light scattering is not limited only to laterally adjacent gate wirings.

Light diffraction refers to phenomena, such as scattering and interference of light waves passing through a plurality of slits of a diffraction grating. However, the cause of the interference is not limited only to light waves passing through adjacent slits. Light waves passing through slits located at farther positions have a slight influence.

Therefore, strictly speaking, light scattering occurring at a gate wiring is not limited to a wiring pitch between the gate wiring and an adjacent gate wiring. Light scattering is affected by all gate wirings provided in a standard cell row in which that gate wiring is present.

For example, if a plurality of gate wirings in a standard cell row have a constant wiring pitch, individual transistors have a constant variation in gate length, so that there is not a variation.

However, even if the gate wiring pitch is constant only in each standard cell, then when the gate wiring pitch varies in a whole standard cell row, the gate lengths of transistors in the standard cell vary due to an influence of gate wiring pitches in other standard cells.

Thus, variations in gate length can be more suppressed when the gate wiring pitch is caused to be constant in the whole standard cell row than when the gate wiring pitch is caused to be constant only in individual standard cells.

Therefore, in the case of a standard cell in which transistors are arranged in a manner such that a plurality of gate wiring pitches are alternately repeated (e.g., the standard cell 400 of FIG. 4), the effect of suppressing variations in gate length is more improved when each single row is formed only of standard cells having the same gate wiring pitch S than when standard cells having the gate wiring pitch S and standard cells having the first gate wiring pitch S0 coexist in the same row.

Also, in the gate wiring pitch structure of the standard cell of FIG. 4, a broad diffusion region suitable for a source terminal and a narrow diffusion region suitable for a drain terminal are alternately provided. In this case, if transistors are vertically arranged to provide a circuit having two or more inputs, a broad diffusion region may be allocated for a drain terminal or a narrow diffusion region may be allocated for a source terminal, resulting in a decrease in the speed of a transistor. Therefore, in a standard cell row having the gate wiring pitch structure of FIG. 4, a one-input logic cell, such as an inverter or a buffer, is preferably provided.

In the semiconductor integrated circuit 500 of FIG. 5, a standard cell row having the gate wiring pitch structure of FIG. 4 is applied to the output circuit section 505, and the repeater block 502 relaying between the circuit blocks 501 and 503. Both the output circuit section 505 and the repeater block 502 are generally a block for driving a long-distance wiring, and therefore, a high-speed inverter or buffer is generally used therein. In addition, when signal communication is performed between circuit blocks, 10 to 100 channels of signals are transferred, and therefore, the same number of inverters or buffers having the same function as the number of signals need to be arranged in parallel.

Therefore, a structure in which the inverters of FIG. 4 are provided in the same standard cell row is applied to the repeater block 502 or the output circuit section 505, thereby making it possible to provide a repeater block or an output circuit section including transistors having high speed and small variations in gate length.

The numbers of the flip-flops 507 and 510 and the inverters 508 and 509 may each be singular or plural.

### Third Example

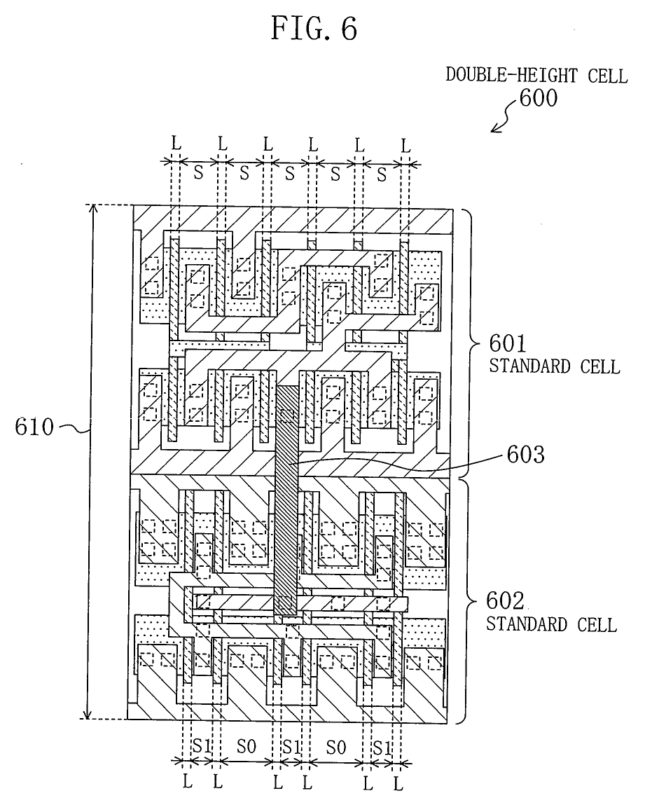

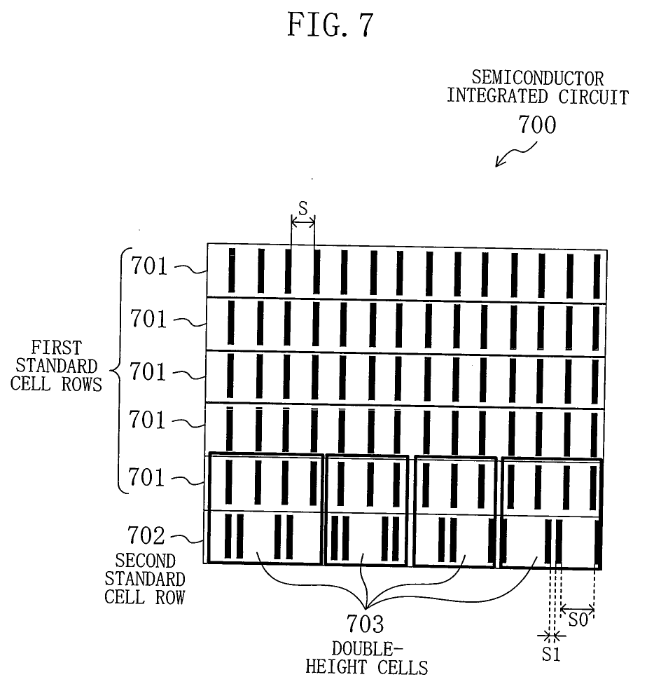

FIG. 6 shows a standard cell according to a third example of the present invention. FIG. 7 shows a semiconductor integrated circuit employing the standard cell of FIG. 6.

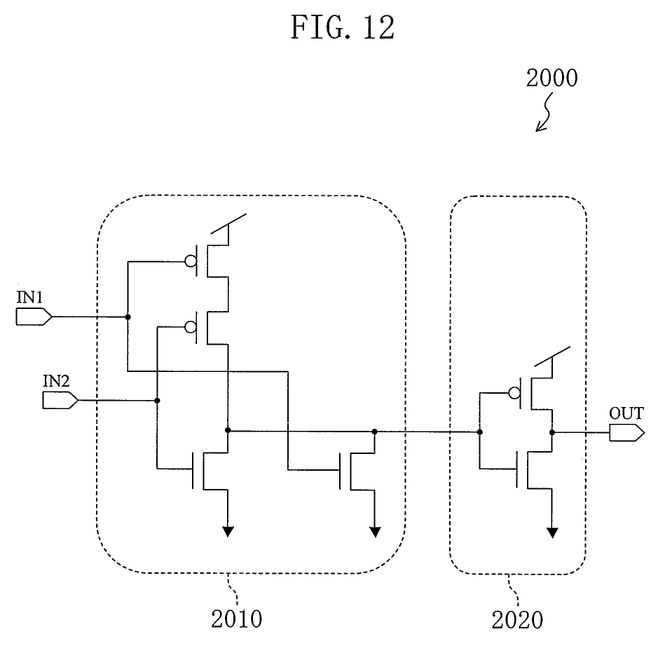

Firstly, FIG. 6 will be described. In FIG. 6, the standard cell 600 is the standard cell of FIG. 12 which comprises an OR logic. The left and ride sides of the standard cell 600 has a length 610 which is two times higher than the width of a standard cell row. The standard cell 600 is referred to as a double-height cell. The double-height cell 600 comprises two standard cells 601 and 602 which are vertically linked together with the lower side of the standard cell 601 and the upper side of the standard cell 602 contact each other.

In the standard cell 601, transistors are arranged in a manner such that a gate wiring pitch thereof is a single constant first wiring pitch S. The standard cell 601 corresponds to the NOR circuit 2010 of FIG. 12.

On the other hand, in the standard cell 602, transistors (first transistors) are arranged in a manner such that a gate wiring pitch thereof includes a second wiring pitch S1 and a third wiring pitch S0 which are alternately repeated, thereby forming an inverter. The standard cell 602 corresponds to the inverter circuit 2020 of FIG. 12.

A signal wiring 603 is arranged to input a signal output from the standard cell 601 to the standard cell 602.

Note that, in FIG. 6, the input terminals and output terminals of the standard cells 600, 601 and 602 are not shown for the sake of simplicity. FIG. 6 has been described.

Next, FIG. 7 will be described. In FIG. 7, the semiconductor integrated circuit 700 comprises a plurality of standard cell rows with the upper side of one standard cell row contact the lower side of another standard cell row above and adjacent to the one standard cell row. The standard cell rows include first standard cell rows 701 and a second standard cell row 702.

In the first standard cell row 701, transistors are arranged in an extending direction of the standard cell row in a manner such that a gate wiring pitch thereof is a single first wiring pitch S.

In the second standard cell row 702, transistors are arranged in an extending direction of the standard cell row in a manner such that a gate wiring pitch thereof includes a second wiring pitch S1 and a third wiring pitch S0 which are alternately repeated.

The double-height cell 703 is the standard cell 600 of FIG. 6. An inverter (i.e., the standard cell 602) included in the standard cell 600 is provided in the second standard cell row 702, and a NOR circuit (i.e., the standard cell 601) included in the standard cell 600 is provided in the first standard cell row 701.

Although a plurality of standard cells are provided in the first standard cell row 701, they are not shown for the sake of simplicity.

A standard cell overlapping both the second standard cell row 702 and the first standard cell row 701 adjacent to the second standard cell row 702 may be many other than the double-height cell 703, which are not shown for the sake of simplicity. Signal wirings between standard cells and power source wirings are not shown for the sake of simplicity. FIG. 7 has been described.

The above-described configuration provides effects described below. The semiconductor integrated circuit 700 comprises two kinds of standard cell rows 701 and 702. Firstly, the second standard cell row 702 will be described.

Transistors provided in the second standard cell row 702 are arranged in a manner such that a gate wiring pitch thereof includes the second and third wiring pitches S1 and S0 which are alternately repeated. Therefore, as described in FIG. 4 as well, a broad diffusion region suitable for a source terminal and a narrow diffusion region suitable for a drain terminal are alternately provided. Therefore, if transistors are vertically arranged to provide a circuit having two or more inputs, a broad diffusion region may be allocated for a drain terminal or a narrow diffusion region may be allocated for a source terminal, resulting in a decrease in the speed of a transistor. Therefore, in the standard cell row 702, a one-input logic cell, such as an inverter or a buffer, is preferably provided. Therefore, the second standard cell row 702 may be suitable for arrangement of transistors having a gate wiring pitch which is suitable for an increase in the speed of an inverter, but is not suitable for an increase in the speed of general-purpose circuits.

Next, the first standard cell row 701 will be described. The transistors provided in the first standard cell row 701 have a gate wiring pitch S which is constant independently of their positions. Therefore, the junction capacitance between the source diffusion region and the drain diffusion of each transistor of the standard cell row 701 is constant.

The second standard cell row 702 is not suitable for an increase in the speed of an inverter or a buffer as compared to the first standard cell row 701. This is because, in the case of the standard cell row 702, if the gate wiring pitch is broadened so as to increase the number of CA vias in the source diffusion region, the drain diffusion capacitance increases.

On the other hand, the second standard cell row 702 has a high level of flexibility of design of general-purpose circuits other than inverters or buffers as compared to the first standard cell row 701. This is because the drain diffusion capacitance is constant in the standard cell row 702 even if any transistor is selected, while the junction capacitance of the drain terminal takes a large value or a small value, depending the position of a selected transistor in the standard cell row 701, so that the same transistor has a reduced operating speed, depending on its position.

For example, in a multi-stage cell (e.g., the OR circuit of FIG. 12) in which an inverter and a multi-input logic gate are connected in series, the current drive ability of transistors used in the logic gate may not be very large, because it is only required to drive a load in a standard cell. Instead, the flexibility of arrangement of transistors is desired to be high in order to provide a multi-input circuit structure. Therefore, a standard cell in which transistors forming a multi-input logic gate are provided is preferably provided in the standard cell row 701 because the flexibility is high with respect to the vertically arranged structure.

As described above, the first standard cell row 701 has a high level of design flexibility with respect to general-purpose circuits, though it cannot be used to provide a high-speed inverter. Therefore, the first standard cell row 701 is suitable for construction of a complex logic gate other than inverters.

The standard cell 600 is a double-height cell comprising the standard cell rows 701 and 702. Therefore, when a multi-stage cell is designed, by providing an inverter and other logics in separate standard cell rows, it is possible to design a higher standard cell than in the third conventional example in which only a single gate wiring pitch can be used.

As described above, according to the above-described configuration, the double-height cell 600 can include two kinds of transistors: transistors having a first gate wiring pitch which is suitable for an increase in the speed of an inverter, but is not suitable for an increase in the speed of general-purpose circuits; and transistors having a second gate wiring pitch which cannot increase the speed of an inverter and provides a high level of design flexibility with respect to general-purpose circuits as compared to the first gate wiring pitch. Therefore, in a multi-stage cell having a circuit structure in which the output terminal is driven by an inverter, by using the two kinds of transistors separately for an inverter and other circuits, the flexibility of design of a semiconductor integrated circuit having a higher operating speed is more improved than in the third conventional example.

What is claimed is:

1. A layout structure of a semiconductor integrated circuit employing a standard cell, wherein
the standard cell includes a silicon substrate, a plurality of transistors provided on the silicon substrate and each having a drain diffusion region, a source diffusion region, and a gate wiring, a first wiring layer made of a metal and provided on the silicon substrate, covering the silicon substrate, a second wiring layer made of a metal and provided above the first wiring layer, covering the first wiring layer, and a CA via for connecting the drain diffusion region or the source diffusion region and the first wiring layer,
the standard cell further includes a power source wiring provided in the first wiring layer, and a jumper wiring,
the plurality of transistors are arranged in the standard cell in a manner such that a wiring pitch between each gate wiring thereof is constant,
the plurality of transistors include first and second transistors,
the first transistor and the second transistor are arranged adjacent to each other, sharing a common source diffusion region,
a plurality of first CA vias are provided in the common source diffusion region,
the plurality of first CA vias are each connected to the power source wiring, and
the jumper wiring is provided in the second wiring layer and connects the drain diffusion region of the first transistor and the drain diffusion region of the second transistor.

2. The layout structure of claim 1, wherein the standard cell is an inverter.

3. The layout structure of claim 2, wherein the plurality of transistors included in the standard cell are a plurality of N-channel transistors.

4. A layout structure of a semiconductor integrated circuit having one or more first standard cell rows each including a plurality of standard cells, each standard cell including a power source wiring, a plurality of transistors, and a plurality of CA vias for connecting drain diffusion regions or source diffusion regions of the plurality of transistors and a metal wiring layer,
wherein the plurality of transistors are arranged in a direction parallel to upper and lower sides of the standard cell, gate wirings of the plurality of transistors are arranged in a direction perpendicular to the upper and lower sides of the standard cell, and a wiring pitch between each of the plurality of gate wirings includes a first wiring pitch and a second wiring pitch, the first wiring pitch and the second wiring pitch being alternately repeated,
the first wiring pitch is narrower than the second wiring pitch,
a first source diffusion region which is at least one of the source diffusion regions provided between a pair of gate wirings having the second wiring pitch is connected via a plurality of CA vias to the power source wiring, and
at least one pair of two of the plurality of CA vias are arranged in a direction parallel to the upper and lower sides of the standard cell.

5. The layout structure of claim 4, wherein the standard cell is an inverter or a buffer.

6. The layout structure of claim 5, further including a second standard cell row having a plurality of standard cells including a plurality of transistors arranged in a single gate wiring pitch.

7. The layout structure of claim 6, further including first and second circuit blocks and at least one repeater block,
wherein the repeater block includes at least one of the first standard cell rows including a first standard cell having an inverter or buffer function,
a signal output from the first circuit block is input to the first standard cell, and
a signal output from the first standard cell is input to the second circuit block.

8. The layout structure of claim 7, wherein
the first circuit block includes at least one of the first standard cell rows including the first standard cell having an inverter or buffer function, and
a signal output from the first circuit block is a signal output from the first standard cell and is transferred to the second circuit block.

9. A layout structure of a semiconductor integrated circuit including a plurality of standard cell rows each including a plurality of standard cells, each standard cell including a plurality of transistors each having a diffusion region and a gate wiring, and a plurality of CA vias for connecting drain diffusion regions or source diffusion regions of the plurality of transistors and a metal wiring layer, and the standard cells being arranged in a direction parallel to upper and lower sides of the standard cell, the layout structure including:
a first standard cell row including some of the plurality of transistors arranged at predetermined intervals in a manner such that a wiring pitch between each gate wiring of the transistor is a first wiring pitch S;
a second standard cell row including some of the plurality of transistors arranged in a manner such that a wiring pitch between each gate wiring of the transistor includes a second wiring pitch S1 and a third wiring pitch S0 larger than the second wiring pitch S1, the second wiring pitch S1 and the third wiring pitch S0 being alternately repeated, the first standard cell row and the second standard cell row being vertically adjacent to each other; and
at least one double-height cell overlapping the first and second standard cell rows.

10. The layout structure of claim 9, wherein
the third wiring pitch S0 is larger than the first wiring pitch S, and
the maximum number of CA vias which can be arranged without contacting each other in a direction parallel to the upper and lower sides of the standard cell on a diffusion region between two adjacent gate wirings having the third wiring pitch S0, is larger than the maximum number of CA vias which can be arranged without contacting each other in the direction parallel to the upper and lower sides of the standard cell on a diffusion region between two adjacent gate wirings having the third wiring pitch S.

11. The layout structure of claim 9, wherein
the double-height cell includes a plurality of first transistors, and
the plurality of first transistors are provided in the second standard cell row when the double-height cell is provided in the semiconductor integrated circuit, the plurality of first transistors are arranged in a manner such that a wiring pitch between each of the plurality of gate wirings includes the second wiring pitch S1 and the third wiring pitch S0, the second wiring pitch S1 and the third wiring pitch S0 being alternately repeated, and the plurality of first transistors constitute an output circuit for outputting a signal to be propagated to another one of the standard cells in the semiconductor integrated circuit.

12. The layout structure of claim 11, wherein the output circuit is an inverter.
